(19) United States
(12) Patent Application Publication
(10) Pub. No.: US 2026/0005664 A1
(43) Pub. Date: Jan. 1, 2026

(54) FILTER CIRCUIT, DIPLEXER, RADIO-FREQUENCY FRONT-END CIRCUIT, AND COMMUNICATION DEVICE

(71) Applicant: Murata Manufacturing Co., Ltd., Nagaokakyo-shi (JP)

(72) Inventors: Tomohiro YONEKURA, Nagaokakyo-shi (JP); Rei TAKEHARA, Nagaokakyo-shi (JP)

(21) Appl. No.: 19/175,237

(22) Filed: Apr. 10, 2025

(30) Foreign Application Priority Data
Jun. 27, 2024 (JP) 2024-104138

(51) Int. Cl. H03H 1/00; H03H 7/01; H03H 7/46

(52) U.S. Cl. CPC H03H 1/00; H03H 7/0115; H03H 7/46; H03H 2001/0085

(57) ABSTRACT

A filter circuit is located in a dielectric substrate and includes multiple dielectric layers and a pass band in a range higher than a predetermined frequency. The dielectric substrate includes first and second major surfaces facing each other. External terminals for connection with an external device are on the second major surface. The filter device includes a first terminal, a second terminal, and first and second resonant circuits. The first resonant circuit is connected between the first and second terminals. The second resonant circuit is connected between the first resonant circuit and a ground potential. Each of the first and second resonant circuits includes an LC resonant circuit including a capacitor and an inductor. In the dielectric substrate, a portion of an inductor in the second resonant circuit is on or in a dielectric layer between the first major surface and inductors included in the first resonant circuit.

### CROSS REFERENCE TO RELATED APPLICATIONS

This application claims the benefit of priority to Japanese Patent Application No. 2024-104138 filed on Jun. 27, 2024. The entire contents of this application are hereby incorporated herein by reference.

### BACKGROUND OF THE INVENTION

### 1. Field of the Invention

The present disclosure relates to filter circuits, diplexers, radio-frequency front-end circuits, and communication devices. More specifically, the present disclosure relates to technologies that reduce degradation of filter characteristics due to a shield electrode of an external device.

### 2. Description of the Related Art

Japanese Unexamined Patent Application Publication No. 2017-092546 discloses a diplexer that includes, in a multilayer substrate, a low pass filter (LPF) and a band pass filter (BPF) with a pass band whose frequency range is higher than the pass band of the low pass filter. Generally, each of a low pass filter and a band pass filter defining such a diplexer includes a resonant circuit including an inductor and a capacitor.

### SUMMARY OF THE INVENTION

Such a diplexer is often used, for example, in a mobile terminal, such as a mobile phone or a smartphone. In this case, when a shield electrode included in another device or element disposed in the housing of the mobile terminal is located close to the diplexer, parasitic capacitance is generated between the shield electrode and an inductor included in a filter circuit in the diplexer. This may result in a change in the frequency of an attenuation pole generated by a resonant circuit including the inductor. This makes it difficult to achieve desired filter characteristics and may affect the characteristics of the diplexer.

Example embodiments of the present invention reduce the degradation of filter characteristics of a filter circuit that occurs when an external shield electrode is located close to the filter circuit.

A filter circuit according to an example embodiment of the present disclosure is a filter device in a dielectric substrate including multiple dielectric layers and has a pass band in a range higher than a predetermined frequency. The dielectric substrate includes a first major surface and a second major surface facing each other. An external terminal for connection with an external device is on the second major surface. The filter circuit includes a first terminal, a second terminal, a first resonant circuit, and a second resonant circuit. The first resonant circuit is connected between the first terminal and the second terminal. The second resonant circuit is connected between the first resonant circuit and a ground potential. Each of the first resonant circuit and the second resonant circuit includes an LC resonant circuit that includes a capacitor and an inductor. In the dielectric substrate, a portion of the inductor included in the second resonant circuit is on or in a dielectric layer between the inductor included in the first resonant circuit and the first major surface.

A diplexer according to another example embodiment of the present disclosure includes a dielectric substrate, an input terminal, a first output terminal, a second output terminal, a first filter device, and a second filter device. The dielectric substrate includes a first major surface and a second major surface facing each other and includes multiple dielectric layers. The input terminal, the first output terminal, and the second output terminal are on the second major surface. The first filter device is connected between the input terminal and the first output terminal. The second filter device is connected between the input terminal and the second output terminal. The first filter device has a pass band in a range lower than a first frequency. The second filter device includes a first filter circuit that has a pass band in a range higher than the first frequency. The first filter circuit includes a first resonant circuit and a second resonant circuit. The first resonant circuit is connected between the input terminal and the second output terminal. The second resonant circuit is connected between the first resonant circuit and a ground potential. Each of the first resonant circuit and the second resonant circuit includes an LC resonant circuit that includes a capacitor and an inductor. In the dielectric substrate, a portion of the inductor included in the second resonant circuit is on or in a dielectric layer between the inductor included in the first resonant circuit and the first major surface.

A filter circuit according to an example embodiment of the present disclosure is a high pass filter including two resonant circuits in a dielectric substrate. An inductor included in a resonant circuit (second resonant circuit) connected to a ground electrode is closer to an upper major surface of the dielectric substrate than an inductor included in a resonant circuit (first resonant circuit) between a first terminal for input and a second terminal for output. In such a high pass filter, an attenuation pole generated by the first resonant circuit is located closer to a pass band than an attenuation pole generated by the second resonant circuit. Therefore, by positioning the inductor of the first resonant circuit away from the upper major surface of the dielectric substrate, it is possible to reduce the coupling between a shield electrode of an external device and the inductor of the first resonant circuit even when the shield electrode is located close to the upper side of the dielectric substrate. This in turn makes it possible to reduce the degradation of filter characteristics resulting from the proximity of the external shield electrode.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a block diagram of a communication device that includes a diplexer including a filter circuit according to an example embodiment of the present invention.

FIG. 2 is an example of an equivalent circuit diagram of the diplexer in FIG. 1.

FIG. 3 is an external perspective view of the diplexer in FIG. 1.

FIG. 4 is an exploded perspective view showing an example of a multilayer structure of the diplexer in FIG. 3.

FIG. 5 diagram is a for describing the filter characteristics of the filter circuit included in a diplexer according to an example embodiment of the present invention and a filter circuit of a comparative example.

FIG. 6 is a diagram for describing an inductor layout in a filter circuit according to a first variation of an example embodiment of the present invention.

FIG. 7 is a diagram for describing an inductor layout in a filter circuit according to a second variation of an example embodiment of the present invention.

FIG. 8 is a diagram for describing an inductor layout in a filter circuit according to a third variation of an example embodiment of the present invention.

FIG. 9 is a diagram for describing an inductor layout in a filter circuit according to a fourth variation of an example embodiment of the present invention.

### DETAILED DESCRIPTION OF THE EXAMPLE EMBODIMENTS

Example embodiments of the present disclosure are described below with reference to the drawings. The same reference number is assigned to the same or similar components in the drawings, and the descriptions of those components are not repeated.

### Basic Configuration of Communication Device

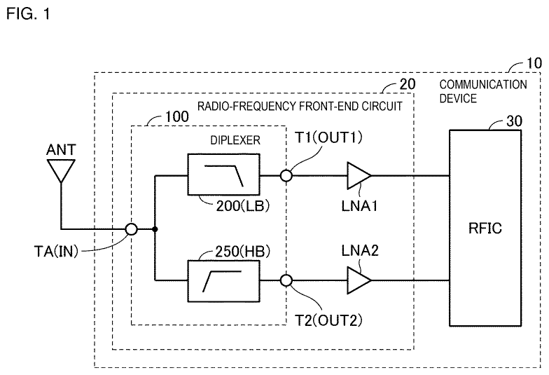

FIG. 1 is a block diagram of a communication device 10 that includes a diplexer 100 including a filter circuit according to an example embodiment. Referring to FIG. 1, the communication device 10 includes a radio-frequency front-end circuit 20 including the diplexer 100 and an RF signal processing circuit (hereafter also referred to as “RFIC”) 30.

The radio-frequency front-end circuit 20 divides a radio frequency signal received by an antenna device ANT into multiple signals in predetermined frequency bands and transmits the signals to a subsequent processing circuit. For example, the radio-frequency front-end circuit 20 is used for communication devices, such as a mobile terminal, like a mobile phone, a smartphone, or a tablet, and a personal computer with a communication function. The radio-frequency front-end circuit 20 illustrated in FIG. 1 is a receiving front-end circuit. The radio-frequency front-end circuit 20 includes the diplexer 100 and amplifier circuits LNA1 and LNA2.

The diplexer 100 includes an input terminal TA, which is a common terminal, output terminals T1 and T2, and filter devices 200 and 250. The diplexer 100 includes the filter device 200 (first filter device) and the filter device 250 (second filter device) that have pass bands with different frequency ranges.

The filter device 200 is connected between the input terminal TA and the output terminal T1. The filter device 200 is a low band filter that has a pass band with a frequency range in a low band (LB) group and has a stopband with a frequency range in a high band (HB) group. The filter device 250 is connected between the input terminal TA and the output terminal T2. The filter device 250 is a high band filter that has a pass band with a frequency range in the high band group and has a stopband with a frequency range in the low band group. In the present example embodiment, the filter device 200 is a low pass filter, and the filter device 250 is a band pass filter.

Each of the filter devices 200 and 250 passes a radio frequency signal that is a portion of a radio frequency signal received by the antenna device ANT and corresponds to its filter pass band. With this configuration, a radio frequency signal received by the antenna device ANT is divided into multiple signals in predetermined frequency bands.

Each of the amplifier circuits LNA1 and LNA2 is a so-called low-noise amplifier. Each of the amplifier circuits LNA1 and LNA2 amplifies a radio frequency signal passed through the diplexer 100 without adding much noise and transmits the amplified radio frequency signal to the RFIC 30.

The RFIC 30 is an RF signal processing circuit that processes radio frequency signals transmitted and received by the antenna device ANT. Specifically, the RFIC 30 performs signal processing, such as down-converting, on a radio frequency signal input from the antenna device ANT via a reception signal path of the radio-frequency front-end circuit 20 and outputs a reception signal generated by the signal processing to a baseband signal processing circuit (not shown).

When the radio-frequency front-end circuit 20 is a receiving front-end circuit as illustrated in FIG. 1, in the diplexer 100, the terminal TA, to which the antenna device ANT is connected, define and function as an input terminal, and the terminals T1 and T2 serve as output terminals. Alternatively, the radio-frequency front-end circuit may be used as a transmitting front-end circuit. In this case, each of the terminals T1 and T2 of the diplexer 100 define and function as an input terminal, and the terminal TA define and function as a common output terminal. Also, in this case, a power amplifier is used instead of a low noise amplifier as an amplifier included in each amplifier circuit.

### Configuration of Diplexer

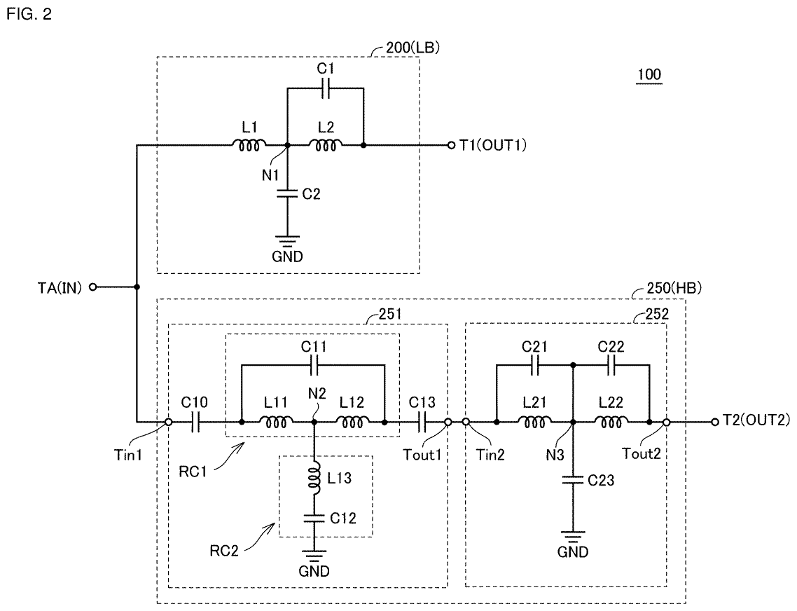

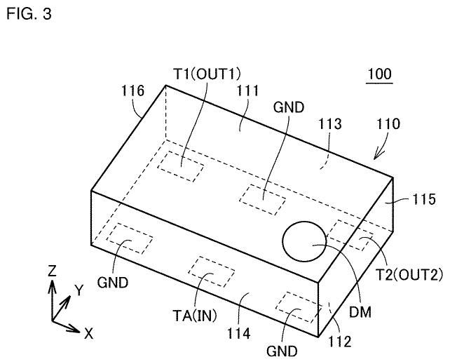

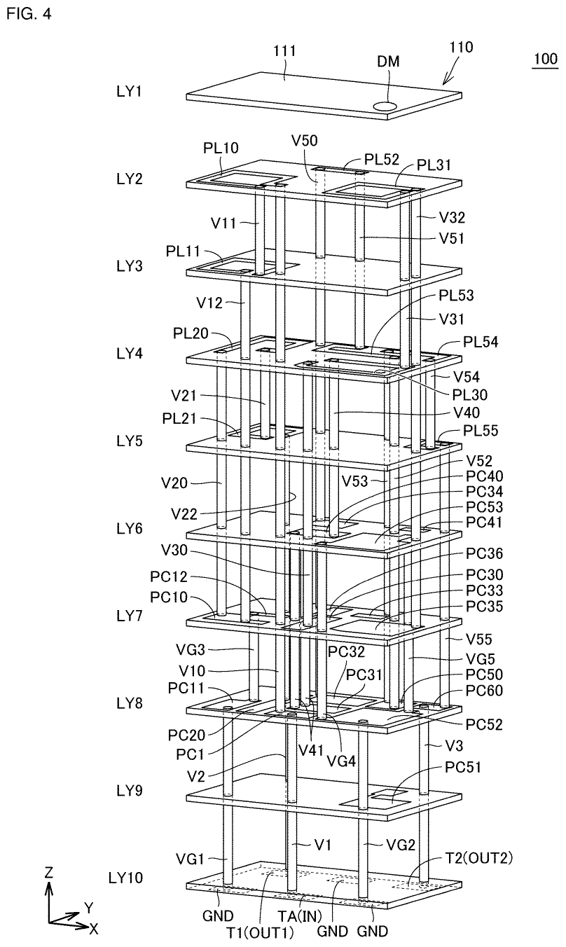

Next, with reference to FIGS. 2 to 4, a detailed configuration of the diplexer 100 is described. FIG. 2 is an example of an equivalent circuit diagram of the diplexer 100 in FIG. 1. Also, FIG. 3 is an external perspective view of the diplexer 100, and FIG. 4 is an exploded perspective view showing an example of a multilayer structure of the diplexer 100.

Referring to FIG. 2, as described above, the filter device 200 is connected between the input terminal TA and the output terminal T1. Also, the filter device 250 is connected between the input terminal TA and the output terminal T2.

The filter device 200 is a low pass filter that includes inductors L1 and L2 and capacitors C1 and C2. A first end of the inductor L1 is connected to the input terminal TA. The inductor L2 is connected between a second end of the inductor L1 and the output terminal T1. That is, the inductors L1 and L2 are connected in series between the input terminal TA and the output terminal T1.

The capacitor C1 is connected between the output terminal T1 and a connection node N1 between the inductors L1 and L2. In other words, the capacitor C1 is connected in parallel with the inductor L2. The capacitor C2 is connected between the connection node N1 and a ground potential GND.

The filter device 250 includes filter circuits 251 and 252 that are connected in series between the input terminal TA and the output terminal T2. The filter circuit 251 is a high pass filter, and the filter circuit 252 is a low pass filter. The cutoff frequency of the filter circuit 252 is higher than the cutoff frequency of the filter circuit 251. Therefore, with the filter circuits 251 and 252, the filter device 250 defines and functions as a band pass filter.

The filter circuit 251 includes a terminal Tin1 connected to the input terminal TA, a terminal Tout1, inductors L11, L12, and L13, and capacitors C10, C11, C12, and C13.

The capacitor C10, the inductors L11 and L12, and the capacitor C13 are connected in series in this order between a terminal Tin1 and a terminal Tout1. The capacitor C11 is connected between a connection node between the capacitor C10 and the inductor L11 and a connection node between the inductor L12 and the capacitor C13. In other words, the capacitor C11 is connected in parallel with the series-connected inductors L11 and L12. That is, an LC parallel resonant circuit (resonant circuit RC1) is provided by the capacitor C11 and the inductors L11 and L12.

A first end of the inductor L13 is connected to a connection node N2 between the inductor L11 and the inductor L12.

A second end of the inductor L13 is connected to the ground potential GND via the capacitor C12. That is, an LC series resonant circuit (resonant circuit RC2) is provided by the inductor L13 and the capacitor C12.

In the filter circuit 251, each of the resonant circuits RC1 and RC2 generates an attenuation pole on the low frequency side of the pass band. More specifically, the resonant circuit RC1 generates an attenuation pole in a range closer to the pass band than the attenuation pole generated by the resonant circuit RC2. In other words, the frequency of the attenuation pole generated by the resonant circuit RC1 is higher than the frequency of the attenuation pole generated by the resonant circuit RC2. Therefore, the influence of the variation in the resonant frequency of the resonant circuit RC1 on the filter characteristics (band width, steepness of attenuation) is greater than the influence of the variation in the resonant frequency of the resonant circuit RC2.

The filter circuit 252 includes a terminal Tin2 connected to the terminal Tout1 of the filter circuit 251, a Tout2 connected to the output terminal T2, inductors L21 and L22, and capacitors C21 to C23.

The inductors L21 and L22 are connected in series between the terminals Tin2 and Tout2. The capacitor C21 is connected in parallel with the inductor L21. Also, the capacitor C22 is connected in parallel with the inductor L22. The capacitor C23 is connected between a connection node N3 between the inductors L21 and L22 and the ground potential GND.

In the diplexer 100 of the example embodiment described above, the filter device 250 for the higher band is a band pass filter. However, the filter device 250 for the higher band may instead be a high pass filter that includes only the filter circuit 251.

Referring to FIGS. 3 and 4, the diplexer 100 includes a dielectric substrate 110 that has a cuboid or substantially cuboid shape and in which multiple dielectric layers LY1 to LY10 are laminated in a predetermined direction. Each dielectric layer of the dielectric substrate 110 may include, for example, a ceramic, such as a low temperature co-fired ceramic (LTCC), or a resin. In the dielectric substrate 110, the inductors and capacitors included in the filter devices 200 and 250 may include multiple electrodes provided on or in the dielectric layers and multiple vias between the dielectric layers. In the descriptions below, for the sake of clarity, it is assumed that the dielectric substrate 110 is a multilayer substrate as described above. However, the dielectric substrate 110 may instead be a single-layer substrate.

In the present application, “via” refers to a conductor that is provided in dielectric layers to connect electrodes formed on or in different dielectric layers. A via is provided by, for example, a conductive paste, plating, and/or a metal pin. In the descriptions below, “Z-axis direction” indicates a direction in which the dielectric layers LY1 to LY10 of the dielectric substrate 110 are laminated, “X-axis direction” indicates a direction that is perpendicular to the Z-axis direction and along the long side of the dielectric substrate 110, and “Y-axis direction” indicates a direction along the short side of the dielectric substrate 110. Also, in the descriptions below, the positive Z-axis direction and the negative Z-axis direction in each drawing may be referred to as “upper” and “lower”, respectively.

The dielectric substrate 110 includes an upper surface 111, a lower surface 112, and side surfaces 113 to 116. On the upper surface 111 of the dielectric substrate 110 (first dielectric layer LY1), a directional mark DM for identifying the orientation of the diplexer 100 is provided. As illustrated in FIG. 3, external terminals (the input terminal TA, the output terminals T1 and T2, and ground terminals GND) to connect the diplexer 100 to an external device are laid out on the lower surface 112 of the dielectric substrate 110 (tenth dielectric layer LY10). That is, the input terminal TA, the output terminals T1 and T2, and the ground terminals GND provide a land grid array (LGA).

In FIG. 4, schematically, the filter device 200 is on the left side (in the negative X-axis direction) of the dielectric substrate 110, and the filter device 250 is on the right side (in the positive X-axis direction) of the dielectric substrate 110.

First, details of the filter device 200 are described. Referring to FIG. 4, the input terminal TA, which is on the lower surface 112 of the dielectric substrate 110 (the tenth dielectric layer LY10), is connected through a via V1 to a capacitor electrode PC1, which has a substantially rectangular shape and is on or in the eighth dielectric layer LY8. Also, the capacitor electrode PC1 is connected through a via V10 to a planar electrode PL10 that is on or in the second dielectric layer LY2.

The planar electrode PL10 is a strip electrode having a substantially U-shape or a substantially O-shape. A first end of the planar electrode PL10 is connected to the via V10. A second end of the planar electrode PL10 is connected to a via V11, and the via V11 is connected to a planar electrode PL11 on or in the third dielectric layer LY3.

The planar electrode PL11 is a strip electrode having a substantially U-shape or a substantially O-shape. A first end of the planar electrode PL11 is connected to the via V11. A second end of the planar electrode PL11 is connected to a via V12, and the via V12 is connected to a capacitor electrode PC10 on or in the seventh dielectric layer LY7. The inductor L1 in FIG. 2 is defined by the vias V10 to V12 and the planar electrodes PL10 and PL11.

The capacitor electrode PC10 has a substantially rectangular shape. In plan view of the dielectric substrate 110 from the Z-axis direction, the capacitor electrode PC10 partially overlaps capacitor electrodes PC11 and PC20 that are on or in the eighth dielectric layer LY8. The capacitor electrode PC11 is connected through a via VG1 to the ground terminal GND on or in the tenth dielectric layer LY10. The capacitor C2 in FIG. 2 is defined by the capacitor electrodes PC10 and PC11.

The capacitor electrode PC20 is a strip electrode that extends in the Y-axis direction. Although hidden by other vias and not clearly visible in FIG. 4, the capacitor electrode PC20 is connected through a via V2 to the output terminal T1 on or in the tenth dielectric layer LY10.

The capacitor electrode PC11 is connected through a via VG3 to a capacitor electrode PC12 on or in the seventh dielectric layer LY7. The capacitor electrode PC12 is a strip electrode that extends in the X-axis direction. In plan view of the dielectric substrate 110 from the Z-axis direction, the capacitor electrode PC12 partially overlaps the capacitor electrode PC20. The capacitor C1 in FIG. 2 is defined by the capacitor electrodes PC12 and PC20.

The capacitor electrode PC10 is also connected through a via V20 to a planar electrode PL20 on or in the fourth dielectric layer LY4. The planar electrode PL20 is a strip electrode having a substantially J-shape. A first end of the planar electrode PL20 is connected to the via V20. A second end of the planar electrode PL20 is connected through a via V21 to a planar electrode PL21 on or in the fifth dielectric layer LY5.

The planar electrode PL21 is a strip electrode having a substantially U-shape or a substantially O-shape. A first end of the planar electrode PL21 is connected to the via V21. A second end of the planar electrode PL21 is connected through a via V22 to the capacitor electrode PC20 on or in the eighth dielectric layer LY8. The inductor L2 in FIG. 2 is defined by the vias V20, V21, and V22 and the planar electrodes PL20 and PL21.

Next, details of the filter device 250 are described. In plan view of the dielectric substrate 110 from the Z-axis direction, the capacitor electrode PC1 on or in the eighth dielectric layer LY8 partially overlaps a capacitor electrode PC30 that has a substantially rectangular shape and is on or in the seventh dielectric layer LY7. The capacitor C10 in FIG. 2 is defined by the capacitor electrodes PC1 and PC30.

The capacitor electrode PC30 is connected through a via V30 to a planar electrode PL30 on or in the fourth dielectric layer LY4. The planar electrode PL30 is a strip electrode having a substantially U-shape or a substantially O-shape. A first end of the planar electrode PL30 is connected to the via V30. A second end of the planar electrode PL30 is connected through a via V40 to a capacitor electrode PC40 that has a substantially rectangular shape and is on or in the sixth dielectric layer LY6.

A via V31 is connected to an intermediate portion of the planar electrode PL30. The via V31 is connected to a planar electrode PL31 on or in the second dielectric layer LY2. The planar electrode PL31 is a strip electrode having a substantially U-shape or a substantially O-shape. A first end of the planar electrode PL31 is connected to the via V31. A second end of the planar electrode PL31 is connected through a via V32 to a capacitor electrode PC35 that has a substantially rectangular shape and is on or in the seventh dielectric layer LY7.

In plan view of the dielectric substrate 110 from the Z-axis direction, at least a portion of the capacitor electrode PC35 overlaps a capacitor electrode PC52 that has a substantially rectangular shape and is on or in the eighth dielectric layer LY8. The capacitor electrode PC52 is connected through a via VG2 to the ground terminal GND on or in the tenth dielectric layer LY10.

The capacitor electrode PC52 is also connected through vias VG4 and VG5 to a capacitor electrode PC53 that has a substantially rectangular shape and on or in the sixth dielectric layer LY6. In plan view of the dielectric substrate 110 from the Z-axis direction, at least a portion of the capacitor electrode PC53 overlaps the capacitor electrode PC35 on or in the seventh dielectric layer LY7.

The inductor L11 in FIG. 2 is provided by a section extending from a point on the planar electrode PL30 connected to the via V31, through the via V30, to the capacitor electrode PC30. The inductor L12 in FIG. 2 is provided by a section extending from a point on the planar electrode PL30 connected to the via V31, through the via V40, to the capacitor electrode PC40.

The inductor L13 in FIG. 2 is defined by the vias V31 and V32 and the planar electrode PL31. Also, the capacitor C12 in FIG. 2 is defined by the capacitor electrodes PC35, PC52, and PC53.

The capacitor electrode PC40 is connected through two vias V41 to a capacitor electrode PC31 that has a substantially rectangular shape and is on or in the eighth dielectric layer LY8. In plan view of the dielectric substrate 110 from the Z-axis direction, the capacitor electrode PC30 partially overlaps the capacitor electrode PC40 on or in the sixth dielectric layer LY6 and the capacitor electrode PC31 on or in the eighth dielectric layer LY8. The capacitor C11 in FIG. 2 is defined by the capacitor electrodes PC30, PC31, and PC40.

At least one of the vias V41 is also connected to a capacitor electrode PC36 on or in the seventh dielectric layer LY7. The capacitor electrode PC36 has a substantially rectangular shape and extends in the Y-axis direction. In plan view of the dielectric substrate 110 from the Z-axis direction, the capacitor electrode PC36 partially overlaps a capacitor electrode PC34 on or in the sixth dielectric layer LY6 and a capacitor electrode PC32 on or in the eighth dielectric layer LY8. The capacitor C13 in FIG. 2 is defined by the capacitor electrodes PC32, PC34, and PC36.

The capacitor electrode PC32 is connected through a via V50 to a planar electrode PL52 on or in the second dielectric layer LY2 and to the capacitor electrode PC34 on or in the sixth dielectric layer LY6. The planar electrode PL52 is a strip electrode extending in the X-axis direction. A first end of the planar electrode PL52 is connected to the via V50. A second end of the planar electrode PL52 is connected through a via V51 to a planar electrode PL53 on or in the fourth dielectric layer LY4.

The planar electrode PL53 is a strip electrode having a substantially J-shape. A first end of the planar electrode PL53 is connected to the via V51. A second end of the planar electrode PL53 is connected through a via V52 to a capacitor electrode PC50 that has a substantially rectangular shape and is on or in the eighth dielectric layer LY8. The inductor L21 in FIG. 2 is defined by the vias V50, V51, and V52 and the planar electrodes PL52 and PL53.

The capacitor electrode PC50 is also connected through a via V53 to a planar electrode PL54 that is on or in the fourth dielectric layer LY4. The planar electrode PL54 is a strip electrode having a substantially L-shape. A first end of the planar electrode PL54 is connected to the via V53. A second end of the planar electrode PL54 is connected through a via V54 to a planar electrode PL55 on or in the fifth dielectric layer LY5.

The planar electrode PL55 has a substantially U-shape, and a first end of the planar electrode PL55 is connected to the via V54. A second end of the planar electrode PL55 is connected to the output terminal T2 on or in the tenth dielectric layer LY10 through a via V55, a capacitor electrode PC60 on or in the eighth dielectric layer LY8, and a via V3. The inductor L22 in FIG. 2 is defined by the vias V3, V53, V54, and V55, the planar electrodes PL54 and PL55, and the capacitor electrode PC60.

In plan view of the dielectric substrate 110 from the Z-axis direction, the capacitor electrode PC50 and the capacitor electrode PC60 partially overlap a capacitor electrode PC41 on or in the sixth dielectric layer LY6. The capacitor C22 in FIG. 2 is defined by the capacitor electrodes PC41, PC50, and PC60.

In plan view of the dielectric substrate 110 from the Z-axis direction, the capacitor electrode PC50 and the capacitor electrode PC52 partially overlap a capacitor electrode PC51 on or in the ninth dielectric layer LY9. The capacitor C23 in FIG. 2 is defined by the capacitor electrodes PC50, PC51, and PC52.

Furthermore, in plan view of the dielectric substrate 110 from the Z-axis direction, the capacitor electrode PC50 and the capacitor electrode PC32 partially overlap a capacitor electrode PC33 on or in the seventh dielectric layer LY7. The capacitor C21 in FIG. 2 is defined by the capacitor electrodes PC32, PC33, and PC50.

As illustrated in FIG. 4, the capacitor electrodes defining capacitors in each filter device are on or in dielectric layers that are located in a region from the middle to the lower surface 112 of the dielectric substrate 110. In other words, electrodes defining the capacitors are on or in dielectric layers between the inductors and the lower surface 112.

Also, in plan view of the filter circuit 251 from the normal direction of the dielectric substrate 110, at least a portion of the planar electrode PL30 included in the inductors L11 and L12 overlaps the planar electrode PL31 included in the inductor L13.

### Influence of External Shield Electrode

A diplexer as described above is often used, for example, in a mobile terminal, such as a mobile phone or a smartphone. In such a case, when a shield electrode included in another device or element disposed in the housing of the mobile terminal is located close to the diplexer, magnetic flux generated by an inductor included in a filter circuit in the diplexer is blocked by the shield and as a result, the inductance of the inductor changes. This may result in a change in the frequency of an attenuation pole generated by a resonant circuit including the inductor, make it difficult to obtain desired filter characteristics, and influence the characteristics of the diplexer.

In general, when magnetic flux generated by an inductor is blocked, the inductance of the inductor decreases, and as a result, the resonant frequency of a resonant circuit constituted by the inductor increases. That is, the frequency of the attenuation pole generated by the resonant circuit increases. This particularly influences the bandpass characteristics of a high pass filter on the high band side, resulting in a decrease in the band width of the pass band of the high pass filter.

Generally, the amount of magnetic flux blocked by the external shield electrode increases as the distance between the inductor and the external shield electrode decreases. Therefore, in a high pass filter on the high band side of the diplexer according to the present example embodiment, an inductor, which is included in a resonant circuit that generates an attenuation pole closest to the pass band, is located in a position at which the magnetic flux is less likely to be blocked by the external shield electrode to reduce the degradation of filter characteristics resulting from the proximity of the external shield electrode.

More specifically, when the diplexer is provided in the dielectric substrate 110 as illustrated in FIG. 3, because the lower surface 112 of the dielectric substrate 110 define and function as the mounting surface, the external shield electrode is located close to the upper surface 111 of the dielectric substrate 110. Therefore, the inductor included in a resonant circuit, which generates an attenuation pole closest to the pass band of the high pass filter, is located in the dielectric substrate 110 as far as possible from the upper surface 111. This reduces the blocking, by the external shield electrode, of magnetic flux generated by an inductor, which is likely to influence filter characteristics, and thus makes it possible to reduce the degradation of filter characteristics resulting from the proximity of the external shield electrode.

### Bandpass Characteristics of Filter Circuit

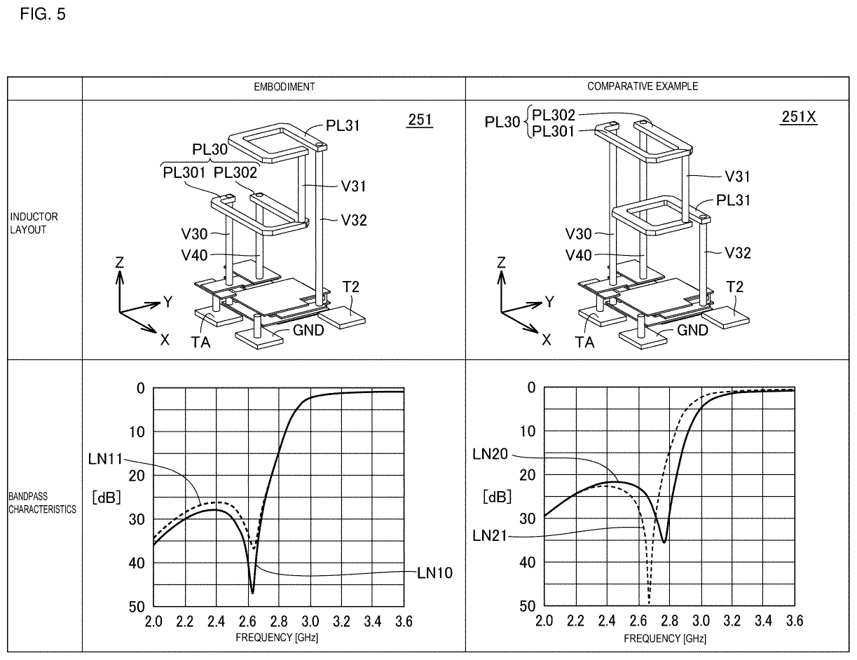

FIG. 5 is a diagram for describing the filter characteristics of the filter circuit 251 included in the diplexer 100 of the present example embodiment and a filter circuit 251X of a comparative example. The upper row of FIG. 5 includes perspective views showing inductor layouts in the filter circuits according to the present example embodiment and the comparative example. The lower row of FIG. 5 includes graphs showing bandpass characteristics of the filter circuits.

The diagrams of inductor layouts in the upper row focus on the structures of inductors included in high pass filters of the filter devices on the high band side. Also, a portion of the planar electrode PL30 included in the inductor L11 is referred to as a planar electrode PL301, and a portion of the planar electrode PL30 included in the inductor L12 is referred to as a planar electrode PL302.

Also, in each graph in the lower row, the horizontal axis indicates a frequency, and the vertical axis indicates insertion loss from the terminal Tin1 to the terminal Tout1. Each of dotted lines LN11 and LN21 indicates insertion loss caused solely by the filter. Each of solid lines LN10 and LN20 indicates insertion loss caused when the external shield electrode is located close to a position above the upper surface 111 of the dielectric substrate 110.

In the filter circuit 251 of the present example embodiment, the planar electrode PL31 included in the inductor L13 defining the resonant circuit RC2 is closer to the upper surface 111 of the dielectric substrate 110 than the planar electrode PL30 included in the inductors L11 and L12 defining the resonant circuit RC1. That is, in the filter circuit 251, the planar electrode PL31 is on or in a dielectric layer between the upper surface 111 of the dielectric substrate 110 and the planar electrode PL30.

In contrast, in the filter circuit 251X of the comparative example, the planar electrode PL30 for the resonant circuit RC1 is closer to the upper surface 111 than the planar electrode PL31 for the resonant circuit RC2. That is, in the filter circuit 251X, the planar electrode PL30 is on or in a dielectric layer between the upper surface 111 of the dielectric substrate 110 and the planar electrode PL31.

As described with reference to FIG. 2, the attenuation pole generated by the resonant circuit RC1 is closer to the pass band than the attenuation pole generated by the resonant circuit RC2. Therefore, with the comparative example in which the planar electrode PL30 included in the resonant circuit RC1 is closer to the upper surface 111, when the external shield electrode is located close to the upper surface 111 of the dielectric substrate 110, the attenuation pole (dotted line LN21) around 2.65 GHZ shifts toward the high frequency side around 2.75 GHz (solid line LN20). That is, the range of the pass band decreases.

In contrast, with the present example embodiment, because the planar electrode PL30 included in the resonant circuit RC1 is farther from the upper surface 111 than in the comparative example, the coupling with the external shield electrode is reduced. Therefore, as shown in the graph, the frequency of the attenuation pole hardly changes even when the external shield electrode is located close to the upper surface 111. As a result, regardless of whether the external shield electrode is present, the attenuation curves near the low frequency side of the pass band have substantially the same shape. That is, with the filter circuit 251 of the present example embodiment, the degradation of filter characteristics resulting from the proximity of the external shield electrode is reduced.

As described above, in a high pass filter including a parallel resonant circuit between an input-side terminal and an output-side terminal in a dielectric substrate and a series resonant circuit between the parallel resonant circuit and a ground potential, an inductor included in the parallel resonant circuit is farther from an upper surface of the dielectric substrate than an inductor included in the series resonant circuit. This makes it possible to reduce the degradation of filter characteristics that occurs when an external shield electrode is located close to the upper surface of the dielectric substrate.

Also, with a diplexer including such a high pass filter, a radio-frequency front-end circuit including the diplexer, and a communication device including the diplexer, it is possible to reduce the degradation of filter characteristics that occurs when an external shield electrode is located close to the diplexer.

“Filter circuit 251” and “filter circuit 252” in the present example embodiment correspond to “first filter circuit” and “second filter circuit”, respectively. “Output terminal T1” and “output terminal T2” in the present example embodiment correspond to “first output terminal” and “second output terminal”, respectively. “Terminal Tin1” and “terminal Tout1” in the present example embodiment correspond to “first terminal” and “second terminal”, respectively. “Major surface 111” and “major surface 112” in the present example embodiment correspond to “first major surface” and “second major surface”, respectively. “Resonant circuit RC1” and “resonant circuit RC2” in the present example embodiment correspond to “first resonant circuit” and “second resonant circuit”, respectively. “Inductor L11”, “inductor L12”, and “inductor L13” in the present example embodiment correspond to “first inductor”, “second inductor”, and “third inductor”, respectively. “Capacitor C11”, “capacitor C12”, and “capacitor C10” in the present example embodiment correspond to “first capacitor”, “second capacitor”, and “third capacitor”, respectively.

### Variations

In the configuration described in the example embodiments described above, the planar electrodes PL301 and PL302 included in the planar electrode PL30 are on or in the same dielectric layer. In the configurations according to the variations of example embodiments of the present invention described below, the planar electrode PL301 and the planar electrode PL302 are on or in different dielectric layers.

In the configurations according to a first variation and a second variation, a planar electrode included in the inductor L11 is closer to the upper surface 111 of the dielectric substrate 110 than a planar electrode included in the inductor L13. In the configurations according to a third variation and a fourth variation, a planar electrode included in the inductor L13 is closer to the upper surface 111 of the dielectric substrate 110 than a planar electrode included in the inductor L11.

### First Variation

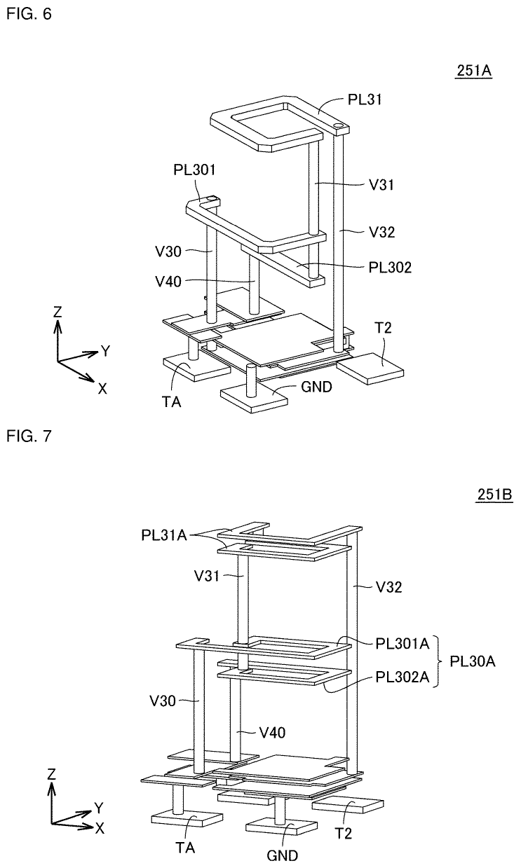

FIG. 6 is a diagram for describing an inductor layout in a filter circuit 251A according to the first variation. In the filter circuit 251A of the first variation, the planar electrode PL302 in the filter circuit 251 illustrated in FIG. 5 is closer to the lower surface 112 of the dielectric substrate 110 than the planar electrode PL301. Also, the via V31, which connects the planar electrode PL30 to the planar electrode PL31, extends from the planar electrode PL31 to the planar electrode PL302 through the planar electrode PL301.

In other words, the planar electrode PL301 is on or in a dielectric layer between the planar electrode PL31 and the planar electrode PL302.

Also, in the filter circuit 251A, the planar electrodes PL301 and PL302 included in the inductors L11 and L12 are farther from the upper surface 111 of the dielectric substrate 110 than the planar electrode PL31 in the inductor L13. This makes it possible to reduce the degradation of filter characteristics even when an external shield electrode is located close to the upper surface 111 of the dielectric substrate 110.

### Second Variation

FIG. 7 is a diagram for describing an inductor layout of a filter circuit 251B according to the second variation. In the filter circuit 251B of the third variation, the planar electrodes PL30 and PL31 in the filter circuit 251 illustrated in FIG. 5 are replaced with planar electrodes PL30A and PL31A.

In the filter circuit 251B, each of the planar electrodes PL30A and PL31A is a helical coil that is wound across multiple dielectric layers. In the example of FIG. 7, each of the planar electrodes PL30A and PL31A is wound across two dielectric layers.

The planar electrode PL30A includes a planar electrode PL301A that is included in the inductor L11 and on or in one of the two dielectric layers and a planar electrode PL302A that is included in the inductor L12 and located on or in the other one of the two dielectric layers. In the filter circuit 251B, the planar electrode PL302A is closer to the lower surface 112 of the dielectric substrate 110 than the planar electrode PL301A. The via V31, which connects the planar electrode PL30A to the planar electrode PL31A, extends from the planar electrode PL31A to the planar electrode PL302A via the planar electrode PL301A.

In other words, the planar electrode PL301A is on or in a dielectric layer between the planar electrode PL31A and the planar electrode PL302A.

In plan view of the filter circuit 251B from the normal direction of the dielectric substrate 110, at least a portion of the planar electrode PL31A overlaps the planar electrode PL30A.

Also in the filter circuit 251B, the planar electrodes PL301A and PL302A included in the inductors L11 and L12 are farther from the upper surface 111 of the dielectric substrate 110 than the planar electrode PL31A included in the inductor L13. This makes it possible to reduce the degradation of filter characteristics even when an external shield electrode is located close to the upper surface 111 of the dielectric substrate 110.

### Third Variation

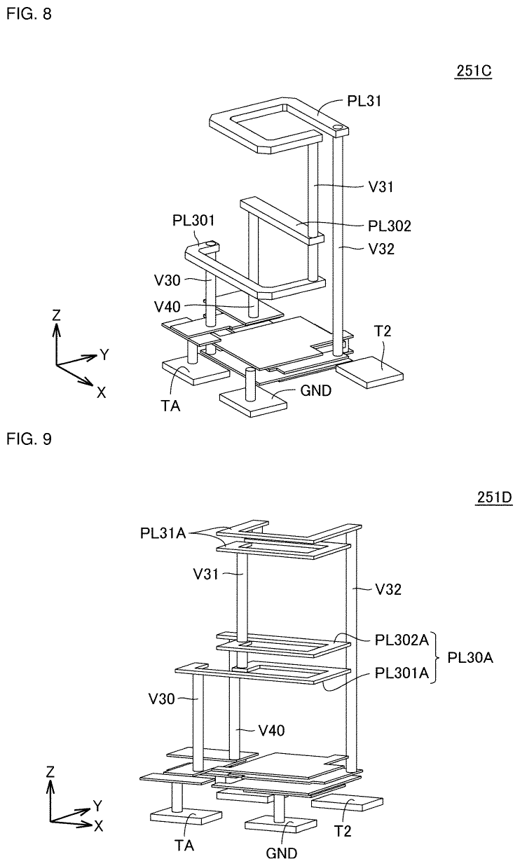

FIG. 8 is a diagram for describing an inductor layout of a filter circuit 251C according to the third variation. In the filter circuit 251C of the third variation, the planar electrode PL301 in the filter circuit 251 illustrated in FIG. 5 is closer to the lower surface 112 of the dielectric substrate 110 than the planar electrode PL302. The via V31, which connects the planar electrode PL30 to the planar electrode PL31, extends from the planar electrode PL31 to the planar electrode PL301 via the planar electrode PL302.

In other words, the planar electrode PL302 is on or in a dielectric layer between the planar electrode PL31 and the planar electrode PL301.

Also in the filter circuit 251C, the planar electrodes PL301 and PL302 included in the inductors L11 and L12 are farther from the upper surface 111 of the dielectric substrate 110 than the planar electrode PL31 included in the inductor L13. This makes it possible to reduce the degradation of filter characteristics even when an external shield electrode is located close to the upper surface 111 of the dielectric substrate 110.

### Fourth Variation

FIG. 9 is a diagram for describing an inductor layout in a filter circuit 251D according to the fourth variation. In the filter circuit 251D of the fourth variation, similarly to the filter circuit 251B of the second variation illustrated in FIG. 7, the planar electrodes PL30A and PL31A are provided instead of the planar electrodes PL30 and PL31 of the filter circuit 251.

However, in the filter circuit 251D, the planar electrode PL301A in the planar electrode PL30A is closer to the lower surface 112 of the dielectric substrate 110 than the planar electrode PL302A. Also, the via V31, which connects the planar electrode PL30A to the planar electrode PL31A, extends from the planar electrode PL31A to the planar electrode PL301A via the planar electrode PL302A. In other words, the planar electrode PL302A is on or in a dielectric layer between the planar electrode PL31A and the planar electrode PL301A.

Also in the filter circuit 251D, the planar electrodes PL301A and PL302A included in the inductors L11 and L12 are farther from the upper surface 111 of the dielectric substrate 110 than the planar electrode PL31A included in the inductor L13. This makes it possible to reduce the degradation of filter characteristics even when an external shield electrode is located close to the upper surface 111 of the dielectric substrate 110.

The above-disclosed example embodiments should be considered as examples and not restrictive in all respects. The scope of the present invention is defined by the scope of the claims rather than by the above descriptions of the example embodiments and is intended to include all modifications within the scope of the claims and the meaning and scope of equivalents.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A filter circuit comprising:
multiple dielectric layers included in a dielectric substrate including a first major surface and a second major surface facing each other and an external terminal for connection with an external device on the second major surface;
a pass band in a range higher than a predetermined frequency;
a first terminal;
a second terminal;
a first resonant circuit connected between the first terminal and the second terminal; and
a second resonant circuit connected between the first resonant circuit and a ground potential; wherein
each of the first resonant circuit and the second resonant circuit includes an LC resonant circuit including a capacitor and an inductor; and
in the dielectric substrate, a portion of the inductor included in the second resonant circuit is on or in a dielectric layer between the inductor included in the first resonant circuit and the first major surface.

2. The filter circuit according to claim 1, wherein
the first resonant circuit includes:
a first inductor with a first end connected to the first terminal;
a second inductor connected between a second end of the first inductor and the second terminal; and
a first capacitor connected in parallel with the first inductor and the second inductor, which are connected in series.

3. The filter circuit according to claim 2, wherein the second resonant circuit includes a third inductor and a second capacitor that are connected in series between the ground potential and a connection node between the first inductor and the second inductor.

4. The filter circuit according to claim 3, wherein, in the dielectric substrate, electrodes of the first capacitor and the second capacitor are on or in dielectric layers between the third inductor and the second major surface.

5. The filter circuit according to claim 3, wherein in plan view of the dielectric substrate from a normal direction of the first major surface, at least a portion of a coil including the first inductor and the second inductor overlaps a coil including the third inductor.

6. The filter circuit according to claim 2, wherein
each of the first inductor and the second inductor includes a planar electrode and a via in the dielectric substrate; and
at least a portion of the planar electrode of the first inductor is in or on a same dielectric layer as the planar electrode of the second inductor.

7. The filter circuit according to claim 1, wherein
a frequency of an attenuation pole defined by the first resonant circuit is closer to a pass band than a frequency of an attenuation pole defined by the second resonant circuit.

8. The filter circuit according to claim 1, further comprising:
a third capacitor connected between the first terminal and the first resonant circuit.

9. A diplexer comprising:
a dielectric substrate including a first major surface and a second major surface facing each other and multiple dielectric layers;
an input terminal, a first output terminal, and a second output terminal on the second major surface;
a first filter device connected between the input terminal and the first output terminal; and
a second filter device connected between the input terminal and the second output terminal; wherein
the first filter device has a pass band in a range lower than a first frequency;
the second filter device includes a first filter circuit that has a pass band in a range higher than the first frequency; the first filter circuit includes:
a first resonant circuit connected between the input terminal and the second output terminal; and
a second resonant circuit connected between the first resonant circuit and a ground potential;
each of the first resonant circuit and the second resonant circuit includes an LC resonant circuit including a capacitor and an inductor; and
in the dielectric substrate, a portion of the inductor included in the second resonant circuit is on or in a dielectric layer between the inductor included in the first resonant circuit and the first major surface.

10. The diplexer according to claim 9, wherein
the second filter device further includes a second filter circuit connected between the first filter circuit and the second output terminal;
the second filter circuit has a pass band in a range lower than a second frequency;
the second frequency is higher than the first frequency; and
with the first filter circuit and the second filter circuit, the second filter device functions as a band pass filter.

11. The diplexer according to claim 9, wherein
the first resonant circuit includes:
a first inductor with a first end connected to the first terminal;
a second inductor connected between a second end of the first inductor and the second terminal; and
a first capacitor connected in parallel with the first inductor and the second inductor, which are connected in series.

12. The diplexer according to claim 11, wherein the second resonant circuit includes a third inductor and a second capacitor that are connected in series between the ground potential and a connection node between the first inductor and the second inductor.

13. The diplexer according to claim 12, wherein, in the dielectric substrate, electrodes of the first capacitor and the second capacitor are on or in dielectric layers between the third inductor and the second major surface.

14. The diplexer according to claim 12, wherein in plan view of the dielectric substrate from a normal direction of the first major surface, at least a portion of a coil including the first inductor and the second inductor overlaps a coil including the third inductor.

15. The diplexer according to claim 11, wherein
each of the first inductor and the second inductor includes a planar electrode and a via in the dielectric substrate; and
at least a portion of the planar electrode of the first inductor is in or on a same dielectric layer as the planar electrode of the second inductor.

16. The diplexer according to claim 9, wherein
a frequency of an attenuation pole defined by the first resonant circuit is closer to a pass band than a frequency of an attenuation pole defined by the second resonant circuit.

17. The diplexer according to claim 9, further comprising:
a third capacitor connected between the first terminal and the first resonant circuit.

18. A radio-frequency front-end circuit comprising:
the diplexer according to claim 9.

19. A communication device comprising:
the radio-frequency front-end circuit according to claim 18.
